(19) United States
(12) Patent Application Publication
(10) Pub. No.: US 2020/0411407 A1
(43) Pub. Date: Dec. 31, 2020

(54) INTEGRATED CIRCUIT PACKAGES WITH SOLDER THERMAL INTERFACE MATERIAL

(71) Applicant: Intel Corporation, Santa Clara, CA (US)

(72) Inventors: Manish Dubey, Chandler, AZ (US); Sergio Antonio Chan Arguedas, Chandler, AZ (US)

(73) Assignee: Intel Corporation, Santa Clara, CA (US)

(21) Appl. No.: 16/453,378

(22) Filed: Jun. 26, 2019

(51) Int. Cl. H01L 23/373; H01L 23/367; H01L 25/065

(52) U.S. Cl. CPC H01L 23/3733; H01L 23/3675; H01L 2225/06589; H01L 2225/06513; H01L 2225/06517; H01L 25/0652

(57) ABSTRACT

Disclosed herein are integrated circuit (IC) packages with solder thermal interface materials (STIM), as well as related methods and devices. For example, in some embodiments, an IC package may include a package substrate, a lid, a die between the package substrate and the lid, and a STIM between the die and the lid. The STIM may have a thickness that is less than 200 microns.

### BACKGROUND

Many electronic devices generate significant amounts of heat during operation. Some such devices include heat sinks or other components to enable the transfer of heat away from heat-sensitive elements in these devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1-3 are side, cross-sectional views of example integrated circuit (IC) packages with solder thermal interface materials (STIMs), in accordance with various embodiments.

FIGS. 4A-4B illustrate various stages in the manufacture of an IC package with a STIM, in accordance with various embodiments.

FIGS. 5A-5B are side, cross-sectional views of an IC assembly that may include a STIM, in accordance with various embodiments.

FIG. 6 is a top view of a wafer and dies that may be included in an IC package with a STIM, in accordance with various embodiments.

FIG. 7 is a side, cross-sectional view of an IC device that may be included in an IC package with a STIM, in accordance with various embodiments.

FIG. 8 is a side, cross-sectional view of an IC assembly that may include an IC package with a STIM, in accordance with various embodiments.

FIG. 9 is a block diagram of an example electrical device that may include an IC package with a STIM, in accordance with various embodiments.

### DETAILED DESCRIPTION

Disclosed herein are integrated circuit (IC) packages with solder thermal interface materials (STIM), as well as related methods and devices. For example, in some embodiments, an IC package may include a package substrate, a lid, a die between the package substrate and the lid, and a STIM between the die and the lid. The STIM may have a thickness that is less than 200 microns.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

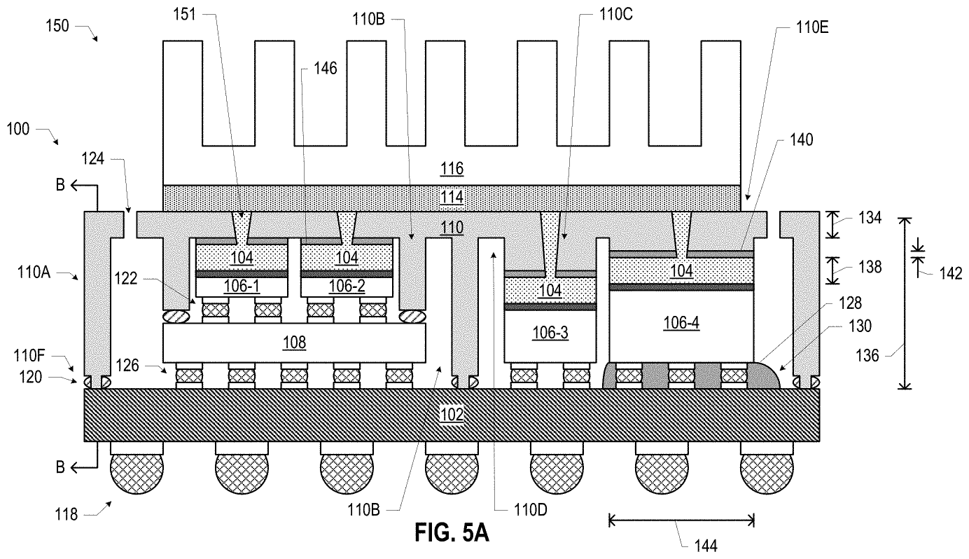

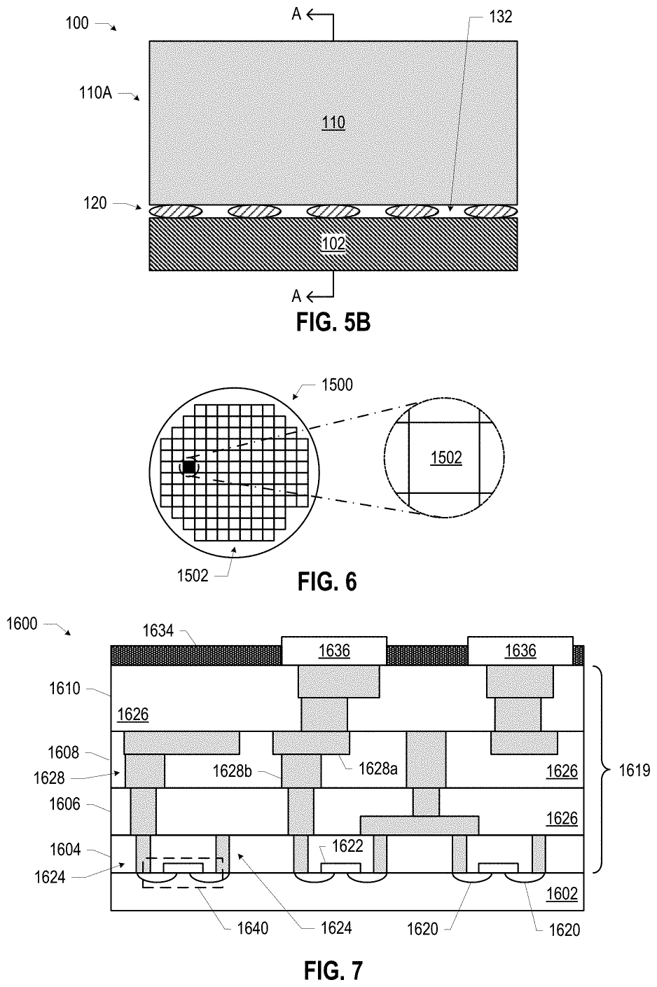

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y. For convenience, the phrase “FIG. 4” may be used to refer to the collection of drawings of FIGS. 4A-4B, the phrase “FIG. 5” may be used to refer to the collection of drawings of FIGS. 5A-5B, etc.

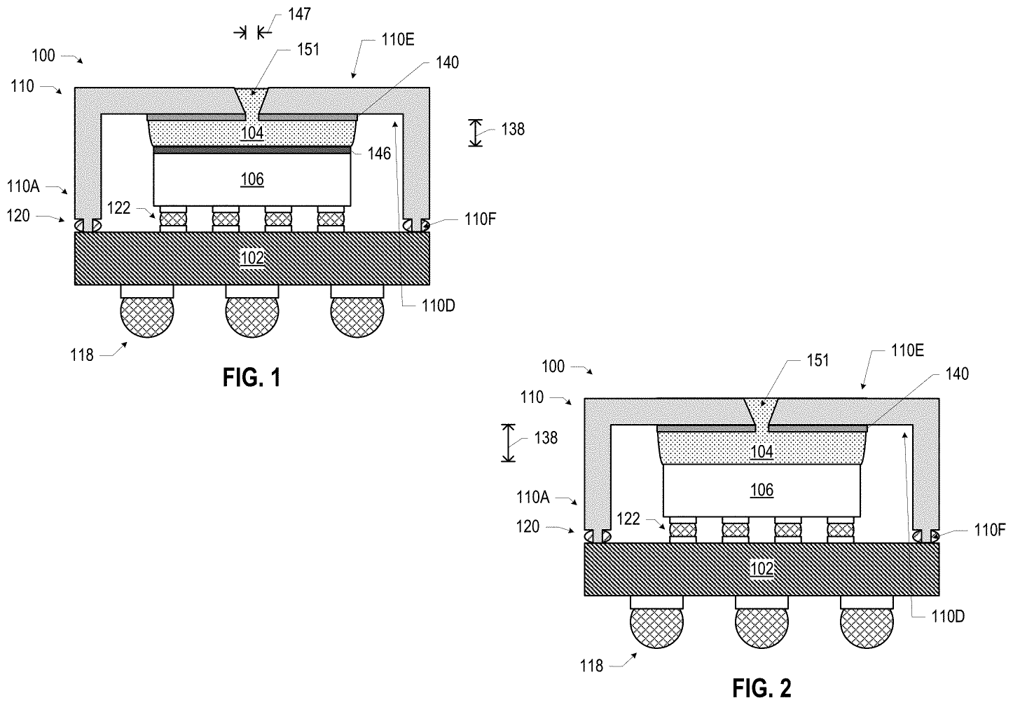

FIG. 1 is a side, cross-sectional view of an example IC package 100 with a STIM 104. The IC package 100 of FIG. 1 includes certain components arranged in a particular manner, but this is simply illustrative, and an IC package 100 in accordance with the present disclosure may take any of a number of forms. FIGS. 2-5, discussed further below, illustrate other examples of IC packages 100 in accordance with the present disclosure; any of the elements discussed herein with reference to FIG. 1 may take any of the forms of those elements discussed herein with reference to FIGS. 2-5, and vice versa.

The IC package 100 of FIG. 1 includes a package substrate 102 to which a die 106 is coupled via interconnects 122 (which may be, for example, first-level interconnects). A STIM 104 is in thermal contact with the die 106 and with a lid 110; during operation of the die 106, the STIM 104 may transfer heat generated by the die 106 to the lid 110. The lid 110 may also be referred to as a “heat spreader” or an “integrated heat spreader” when it is included in the IC package 100.

The STIM 104 may include any suitable solder material. For example, the STIM 104 may include a pure indium solder or an indium alloy solder (e.g., an indium-tin solder, an indium-silver solder, an indium-gold solder, or indium-aluminum solder). In such embodiments, to facilitate the coupling between the STIM 104 and the die 106, a top surface of the die 106 may include an adhesion material region 146 to which the STIM 104 may adhere; similarly, an interior surface 110D of the lid 110 may include an adhesion material region 140 to which the STIM 104 may adhere. The adhesion material region 140 on the underside of the lid 110 may include any suitable material to wet the STIM 104. In some embodiments, the adhesion material region 140 may include gold, silver, or indium. The thickness of the adhesion material region 140 may take any suitable value (e.g., between 0.1 microns and 1 micron, or between 70 nanometers and 400 nanometers). The adhesion material region 140 may be patterned on the underside of the lid 110 to control the location of the STIM 104. The adhesion material region 146, like the adhesion material region 140, may include any suitable material to wet the STIM 104, and may take any of the forms of the adhesion material region 140 discussed above. The adhesion material region 146 may be disposed on an underlying dielectric material; in some embodiments, the adhesion material region 146 may be referred to as “back side metallization (BSM).” In some embodiments, a thickness 138 of a portion of the STIM 104 may be less than 200 microns (e.g., between 50 microns and 200 microns).

Although various ones of FIGS. 1-5 illustrate a distinct boundary between the adhesion material region 140 and the STIM 104 (and also between the adhesion material region 146 and the STIM 104), in practice, the adhesion material region 140 and the STIM 104 (and the adhesion material region 146 and the STIM 104) may react and form an intermetallic compound (IMC). For example, when the adhesion material region 140 (adhesion material region 146) includes gold and the STIM 104 includes indium, the resulting IMC may be a gold-indium IMC. In an IC package 100, the adhesion material regions 140/146 may not be distinctly visible; instead, the IMC resulting from the reaction between these adhesion material regions 140/146 and the STIM 104 may be present at these interfaces. As discussed further below, in some embodiments, the adhesion material region 140 and/or the adhesion material region 146 may not be present in an IC package 100.

The lid 110 may include any suitable materials. In some embodiments, the lid 110 may include a core material and an exterior material (on which the adhesion material region 140 is disposed). For example, in some embodiments, the core material may be copper and the exterior material may be nickel (e.g., the copper may be plated with a layer of nickel having a thickness between 5 microns and 10 microns). In another example, the core material may be aluminum and the exterior material may be nickel (e.g., the aluminum may be plated with a layer of nickel having a thickness between 5 microns and 10 microns). In some embodiments, the lid 110 may be substantially formed of a single material (e.g., aluminum).

The lid 110 may include an interior surface 110D and an exterior surface 110E. A portion of the interior surface 110D (e.g., the adhesion material region 140 at the interior surface 110D, when present) may be in contact with the STIM 104. The lid 110 may include one or more dispense holes 151 between the interior surface 110D and the exterior surface 110E, through which liquid STIM 104 may be dispensed onto a top surface of the die 106 (e.g., as discussed below with reference to FIG. 4). The minimum diameter 147 of a dispense hole 151 may take any suitable value; for example, in some embodiments, the minimum diameter 147 of a dispense hole 151 may be between 0.5 millimeters and 5 millimeters (e.g., between 1 millimeter and 2 millimeters). The dispense hole 151 illustrated in FIG. 1 is tapered, narrowing toward the die 106, but a dispense hole 151 may have any desired shape.

Although a single dispense hole 151 is depicted in many of the accompanying drawings, this is simply for ease of illustration, and a lid 110 may include any suitable number of dispense holes 151. Further, the accompanying drawings depict the dispense hole 151 as being substantially filled with the STIM 104, but this is simply for ease of illustration, and a dispense hole 151 may be partially filled with the STIM 104 or may not have any STIM 104 therein.

The lid 110 may include a foot portion 110A that extends toward the package substrate 102, and a sealant 120 (e.g., a polymer-based adhesive) may attach the foot portion 110A of the lid 110 to the top surface of the package substrate 102. The foot portion 110A may include a narrowed portion 110F proximate to the package substrate 102, and the sealant 120 may be at least partially disposed at side faces of the narrowed portion 110F. In some embodiments, the narrowed portion 110F may be in contact with the package substrate 102, and thus may contribute to controlling the height of the interior surface 110D of the lid 110 above the package substrate 102; such height control may be particularly useful when the STIM 104 is initially deposited as a liquid STIM, as discussed below.

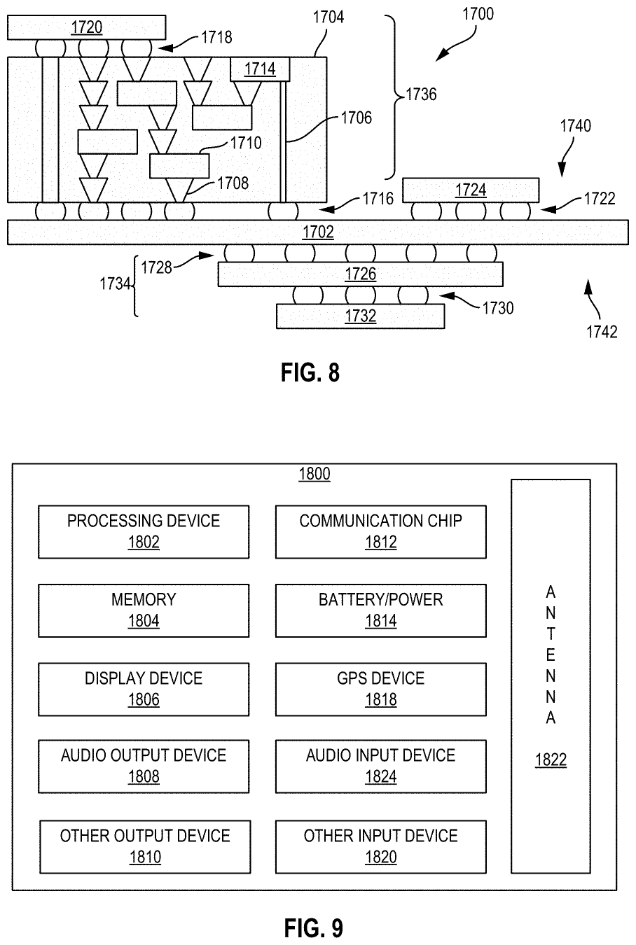

In some embodiments, the interior surface 110D of the lid 110 may be substantially parallel to the top surface of the die 106 (except for the presence of the dispense hole 151), as is depicted in many of the accompanying drawings, but this is simply illustrative, and the interior surface 110D of a lid 110 may have any desired contour. For example, in some embodiments, the interior surface 110D of the lid 110 may be convex, with the distance between the top surface of the die 106 and the interior surface 110D of the lid 110 smaller closer to the center of the die 106 than to the edges of the die 106. The IC package 100 may also include interconnects 118, which may be used to couple the IC package 100 to another component, such as a circuit board (e.g., a motherboard), an interposer, or another IC package, as known in the art and as discussed below with reference to FIG. 8. The interconnects 118 may, in some embodiments, be any suitable second-level interconnects known in the art.

The package substrate 102 may include a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the top and bottom surfaces, or between different locations on the top surface, and/or between different locations on the bottom surface. These conductive pathways may take the form of any of the interconnects 1628 discussed below with reference to FIG. 7 (e.g., including lines and vias). The package substrate 102 may be coupled to the die 106 by interconnects 122, which may include conductive contacts that are coupled to conductive pathways (not shown) through the package substrate 102, allowing circuitry within the die 106 to electrically couple to the interconnects 118 (or to other devices included in the package substrate 102, not shown). As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). The interconnects 122 illustrated in FIG. 1 include solder bumps, but the interconnects 122 may take any suitable form (e.g., wirebonds, a waveguide, etc.). Similarly, the interconnects 118 illustrated in FIG. 1 include solder balls (e.g., for a ball grid array (BGA) arrangement), but any suitable interconnects 118 may be used (e.g., pins in a pin grid array (PGA) arrangement or lands in a land grid array (LGA) arrangement). Further, although the IC package 100 of FIG. 1 includes a die 106 coupled directly to a package substrate 102, in other embodiments (e.g., as discussed below with reference to FIG. 5), an intermediate component may be disposed between the die 106 and the package substrate 102 (e.g., an interposer 108, as illustrated in FIG. 5, a silicon bridge, an organic bridge, etc.).

The die 106 may take the form of any of the embodiments of the die 1502 discussed below with reference to FIG. 6 (e.g., may include any of the embodiments of the IC device 1600 of FIG. 7). The die 106 may include circuitry to perform any desired functionality. For example, the die 106 may be a logic die (e.g., silicon-based dies), a memory die (e.g., high bandwidth memory), or may include a combination of logic and memory. In some embodiments, the IC package 100 may be a server package. In embodiments in which the IC package 100 includes multiple dies 106 (e.g., as discussed below with reference to FIG. 5), the IC package 100 may be referred to as a multi-chip package (MCP). An IC package 100 may include passive components not shown in various ones of the accompanying figures for ease of illustration, such as surface-mount resistors, capacitors, and inductors (e.g., coupled to the top or bottom surface of the package substrate 102). More generally, an IC package 100 may include any other active or passive components known in the art.

The IC packages 100 disclosed herein may be manufactured using a liquid STIM that is then allowed to solidify into the STIM 104. Conventional approaches to using STIMs in IC packages have relied on solder preforms, pre-portioned and shaped sheets of solid solder. During manufacturing, one of these solder preforms is positioned on top of a die, a lid is placed above the solder preform, the entire assembly is heated to melt the solder preform and allow it to wet on the die and the lid, and then the assembly is cooled to solidify the solder. This conventional approach is accompanied by a number of undesirable features. As an initial matter, metal layers are conventionally required on the top side of the die and the underside of the lid to enable the solder to attach to the die and lid, and forming a good joint between the metal layers and the solder has conventionally required the use of a flux material (e.g., a liquid flux applied to the metal layers before the solder preform is positioned). Residue from this flux material (along with air) is typically trapped at the interface between the die and the STIM, and at the interface between the lid and the STIM, during solder solidification. During subsequent reflow processes, the flux residue outgases, resulting in trapped voids (e.g., at the interface between the STIM and the lid), reducing the contact area between the STIM and the lid, and thereby reducing the effective thermal conductivity of the STIM. In conventional IC packages, the amount of voiding may be enough to substantially compromise thermal performance, limiting the materials that may be used and how small the packages may be. For example, the voiding that may occur in conventional IC packages when a liquid flux is used to facilitate the attachment of STIM to the die and the lid may be such that thermal requirements for the IC package cannot be met.

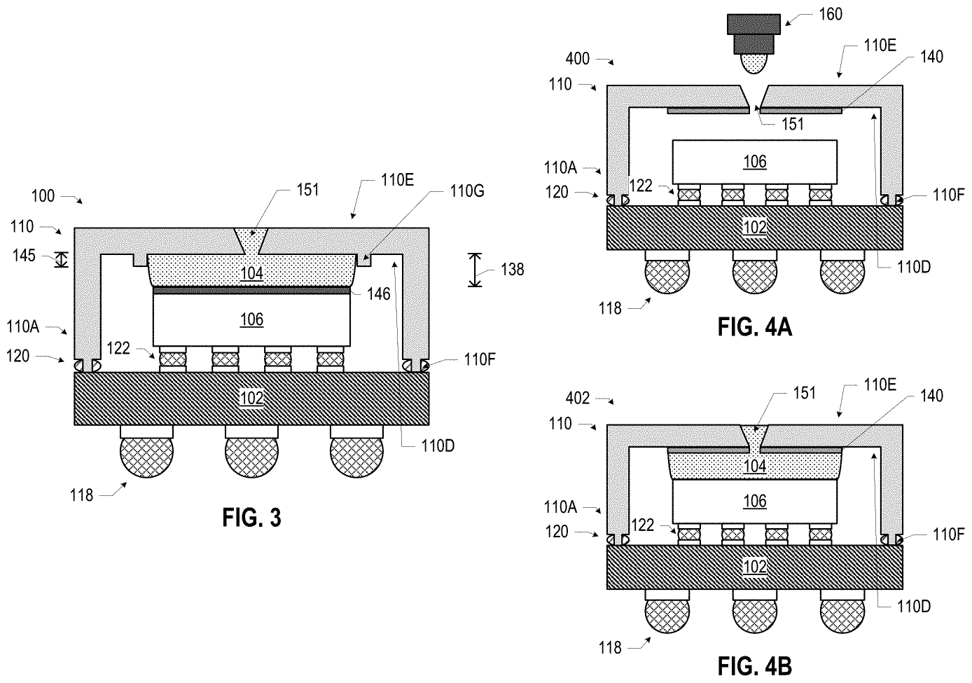

The IC packages 100 disclosed herein may be manufactured using liquid STIMs instead of solder preforms, allowing the IC packages 100 to be manufactured without flux material, and thereby reducing or eliminating outgassing-related voids in the STIM 104. Further, in some embodiments, the adhesion material region 140 and/or the adhesion material region 146 may be omitted (e.g., as discussed below with reference to FIGS. 2-3), reducing the complexity and cost of manufacturing the IC packages 100 relative to conventional IC packages. Additionally, the STIM 104 in the IC packages 100 disclosed herein may have a smaller thickness 138 than is achievable using conventional techniques. For example, conventional solder preforms typically require a STIM thickness greater than 200 microns (e.g., greater than 300 or 400 microns); the STIM 104 disclosed herein may have a thickness 138 that is less than 200 microns.

FIGS. 2-3 are side, cross-sectional views of other example embodiments of IC packages 100. As noted above, many of the elements of the IC packages 100 of FIGS. 2-3 may be shared with the IC package 100 of FIG. 1, and a discussion of these elements is not repeated; these elements may take the form of any of the embodiments discussed above with reference to FIG. 1, for example. Further, any of the features illustrated in FIGS. 1-3 (and FIG. 5) may be combined with any of the other features illustrated in FIGS. 1-3 (and FIG. 5). For example, FIG. 2 illustrates an embodiment in which no adhesion material region 146 is at the top surface of the die 106, and FIG. 3 illustrates an embodiment in which the lid 110 includes a lip portion 110G; the embodiments of FIGS. 2 and 3 may be combined so that an IC package 100, in accordance with the present disclosure, has no adhesion material region 146 at the top surface of the die 106 and the lid 110 includes a lip portion 110G.

As noted above, FIG. 2 depicts an embodiment in which no adhesion material region 146 is at the top surface (e.g., the “back side”) of the die 106. Instead, the STIM 104 may directly contact a dielectric material (e.g., a mold material) that provides the top surface of the die 106. An embodiment like that of FIG. 2 may be fabricated using an initially liquid STIM 104, which may adequately adhere to the dielectric material of the die 106 without an adhesion material region 146. In some embodiments, the dielectric material of the die 106 may be cleaned with liquid flux or formic acid before the initially liquid STIM 104 is provided. An adhesion material region 140 may be part of the lid 110, as discussed above with reference to FIG. 1.

FIG. 3 depicts an embodiment in which no adhesion material region 140 is present on the lid 110, and instead, the lid 110 includes a lip portion 110G that may act as a barrier to constrain the location of the STIM 104. In some embodiments, as shown in FIG. 3, the area encircled by the lip portion 110G may be larger than the surface area of the die 106. The height 145 of the lip portion 110G may take any suitable value; for example, in some embodiments, the height 145 may be between 100 microns and 500 microns. The height 145 of the lip portion 110G may be less than the thickness 138 of the STIM 104, as shown. In some embodiments, the lip portion 110G may be inverted so that the lip portion 110G does not project away from the rest of the lid 110, but instead forms a channel in the lid 110; such a lip portion 110G may also serve to mechanically confine the STIM 104.

As noted above, in some embodiments, the STIM 104 may be formed by initially dispensing the STIM 104 as a liquid through one or more dispense holes 151 onto the top surface of the die 106, and then allowing the liquid STIM 104 to solidify. FIGS. 4A-4B illustrate stages of an example of such a manufacturing process. In particular, FIGS. 4A-4B illustrate an example process for manufacturing the IC package 100 of FIG. 2, but an analogous process may be used to fabricate any suitable ones of the IC packages 100 disclosed herein.

FIG. 4A is a side, cross-sectional view of an assembly 400 in which a lid 110 is disposed over the die 106 and package substrate 102 (as discussed above), and a solder dispense tool 160 is positioned proximate to the dispense hole 151. The solder dispense tool 160 may be configured to dispense liquid STIM at an appropriate temperature (e.g., between 150 degrees Celsius and 180 degrees Celsius for some STIMs). Any suitable dispense tool may be used as the solder dispense tool 160; for example, existing dispense tools for organic material, which dispense the organic material in a temperature range compatible with the temperature ranges appropriate for reflowing STIM, may be used. The spacing between the top surface of the die 106 and the underside of the lid 110 may be controlled by the foot portion 110A of the lid 110 (including the contact between the narrowed portions 110F of the foot portion 110A and the package substrate 102).

FIG. 4B is a side, cross-sectional view of an assembly 402 subsequent to dispensing liquid STIM from the solder dispense tool 160 onto the top surface of the die 106 via the dispense hole 151 of the assembly 400 (FIG. 4A), then allowing the liquid STIM to solidify into the STIM 104. The adhesion material region 140 may help control the location of the STIM 104 (in addition to or instead of a lip portion 110G), and the STIM 104 may or may not extend into the dispense hole 151. In some embodiments, if the dispense hole 151 is not filled by the STIM 104, a thermal grease or other material (not shown) may be used to fill the remainder of the dispense hole 151. The resulting assembly 402 may take the form of the IC package 100.

FIG. 5 depicts various views of example IC assembly 150 including an example IC package 100 with a lid 110; in particular, FIG. 5B is a side, cross-sectional view through the section B-B of FIG. 5A, and FIG. 5A is a side, cross-sectional view through the section A-A of FIG. 5B. Although a particular arrangement of dispense holes 151 and STIM 104 is depicted in FIG. 5, not every STIM 104 need be associated with a dispense hole 151; instead, the lid 110 may include dispense holes 151 (e.g., for liquid STIM) above any one or more of the dies 106, and the STIM 104 associated with other ones of the dies 106 may be formed from solder preforms. More generally, the lid 110 of FIG. 5 may include features or combinations of features that take the form of any of the embodiments discussed above with reference to FIGS. 1-4 (e.g., the arrangement of the adhesion material regions 140/146, the use of lip portions 110G instead of or in addition to the use of adhesion material regions 140, cross-sectional shapes for the dispense holes 151, etc.). Further, any of the elements of FIG. 5 may take the form of any corresponding elements in FIG. 1; discussion of these elements will not be repeated. Similarly, an IC package 100 or an IC assembly 150 may include any combination or subset of the elements of FIGS. 1-5; for example, the IC package 100 of FIG. 1 may include one or more vent holes 124 and/or one or more pedestals 110C, the IC package 100 of FIG. 5 may include fewer or no rib portions 110B, etc.

The IC assembly 150 includes an IC package 100, a heat sink 116, and a TIM 114 therebetween. The TIM 114 may aid in the transfer of heat from the lid 110 to the heat sink 116, and the heat sink 116 may be designed to readily dissipate heat into the surrounding environment, as known in the art. In some embodiments, the TIM 114 may be a polymer TIM or a thermal grease, and may at least partially extend into openings of the dispense holes 151 at the top surface of the lid 110 (not shown).

The IC package 100 of FIG. 5 is an MCP, and includes four dies 106-1, 106-2, 106-3, and 106-4. The particular number and arrangement of dies in FIG. 5 is simply illustrative, and any number and arrangement may be included in an IC package 100. The dies 106-1 and 106-2 are coupled to an interposer 108 by interconnects 122, and the interposer 108 is coupled to the package substrate 102 by interconnects 126 (which may take the form of any of the interconnects 122 disclosed herein, such as first-level interconnects). The interposer 108 may be a silicon interposer (providing conductive pathways between the die 106-1 and the die 106-2), and may or may not include any active devices (e.g., transistors) and/or passive devices (e.g., capacitors, inductors, resistors, etc.). The dies 106-3 and 106-4 are coupled to the package substrate 102 directly. Any of the dies 106 disclosed herein may have any suitable dimensions; for example, in some embodiments, a die 106 may have a side length 144 between 5 millimeters and 50 millimeters.

All of the dies 106 of FIG. 5 include an adhesion material region 146 on the top surface, and the lid 110 includes corresponding adhesion material regions 140 on its underside; different portions of STIM 104 are between corresponding adhesion material regions 140/146; as noted above, in various embodiments, some or all of the adhesion material regions 140 and 146 may be omitted. In some embodiments, the adhesion material region 140 may have a thickness 142 between 0.1 microns and 1 micron; the thickness of the adhesion material region 146 may be in the same range. As discussed above, the thickness of the STIM 104 of FIG. 5 may, in practice, include portions of IMC (not shown) proximate to or in place of the adhesion material regions 140/146; in some embodiments, a portion of IMC may have a thickness between 10 mils and 20 mils.

The lid 110 of FIG. 5 includes a foot portion 110A, as discussed above with reference to FIG. 1, and also includes rib portions 110B and pedestals 110C. In some embodiments, a height 136 of the foot portion 110A may be between 600 microns and 1 millimeter. Rib portions 110B may provide mechanical support to the lid 110, and may control spacing between various elements of the IC package 100 and the lid 110. FIG. 5 illustrates a single rib portion 110B coupled to the package substrate 102 by a sealant 120, and also illustrates two rib portions 110B coupled to a top surface of the interposer 108 by sealant 120. Pedestals 110C may be “downward” projections in the upper portion of the lid 110 that bring the material of the lid 110 into closer proximity with a corresponding die 106; for example, FIG. 5 illustrates pedestals 110C associated with each of the dies 106-3 and 106-4. The pedestals 110C may have adhesion material regions 140 thereon, as shown, and portions of STIM 104 may be disposed between the pedestals 110C and the associated dies 106-3/106-4, as shown. In some embodiments, a minimum thickness 134 of the upper portion of the lid 110 may be between 0.5 millimeters and 4 millimeters (e.g., between 0.5 millimeters and 3 millimeters, or between 0.7 millimeters and 3.5 millimeters).

In some embodiments, the lid 110 may include one or more vent holes 124 in locations that are not above a die 106 (e.g., proximate to the foot portion 110A, as shown). These vent holes 124 may allow gas generated during manufacturing (e.g., gas generated by heated flux on a STIM 104 during BGA processing) to escape into the environment and for pressure to be equalized under and outside of the lid 110. In some embodiments, gaps 132 in the sealant 120 between the foot portion 110A and the package substrate 102 may allow gas to escape (instead of or in addition to the use of vent holes 124) and for pressure to be equalized under and outside of the lid 110; an example of such gaps 132 is illustrated in FIG. 5B.

In some embodiments, an underfill material 128 may be disposed around the interconnects coupling an element to the package substrate 102 (e.g., around the interconnects 126 between the interposer 108 and the package substrate 102, and/or around the interconnects 122 between the dies 106-3/106-4 and the package substrate 102). The underfill material 128 may provide mechanical support to these interconnects, helping mitigate the risk of cracking or delamination due to differential thermal expansion between the package substrate 102 and the dies 106/interposer 108. A single portion of underfill material 128 is depicted in FIG. 5 for ease of illustration, but portions of underfill material 128 may be used in any desired locations. Example materials that may be used for the underfill material 128 include epoxy materials. In some embodiments, the underfill material 128 is created by depositing a fluid underfill material 128 at a location on the package substrate 102 that is next to the die 106 (or other element), and allowing capillary action to draw the fluid underfill material 128 into the area between the die 106 and the package substrate 102. Such a technique may result in an asymmetric distribution of the underfill material 128 relative to the footprint of the die 106 (or other element); in particular, a tongue 130 of underfill material 128 may extend farther out away from the die 106 on the side where the underfill material 128 was initially deposited than on other sides of the die 106. An example of this is shown in FIG. 5A.

The IC packages 100 disclosed herein may include, or may be included in, any suitable electronic component. FIGS. 6-9 illustrate various examples of apparatuses that may be included in any of the IC packages 100 disclosed herein, or may include any of the IC packages 100 disclosed herein.

FIG. 6 is a top view of a wafer 1500 and dies 1502 that may be included in an IC package 100, in accordance with various embodiments. For example, a die 1502 may be a die 106. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 7, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

FIG. 7 is a side, cross-sectional view of an IC device 1600 that may be included in an IC package 100, in accordance with various embodiments. For example, the IC device 1600 may be a die 106. One or more of the IC devices 1600 may be included in one or more dies 1502 (FIG. 6). The IC device 1600 may be formed on a substrate 1602 (e.g., the wafer 1500 of FIG. 6) and may be included in a die (e.g., the die 1502 of FIG. 6). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 6) or a wafer (e.g., the wafer 1500 of FIG. 6).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 7 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 7). Although a particular number of interconnect layers 1606-1610 is depicted in FIG. 7, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 7. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 7. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 7, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 8 is a side, cross-sectional view of an IC assembly 1700 that may include one or more IC packages 100, in accordance with various embodiments. For example, any of the IC packages included in the IC assembly 1700 may be an IC package 100 (e.g., may include a lid 110). The IC assembly 1700 includes a number of components disposed on a circuit board 1702 (which may be, e.g., a motherboard). The IC assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 6), an IC device (e.g., the IC device 1600 of FIG. 7), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include one or more IC packages 100, in accordance with various embodiments. For example, any suitable ones of the components of the electrical device 1800 may include one or more of the IC assemblies 150/1700, IC packages 100, IC devices 1600, or dies 1502 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is an integrated circuit (IC) package, including: a package substrate; a die having a dielectric material at a top surface; a lid, wherein the die is between the package substrate and the lid; and a solder thermal interface material (STIM) between the die and the lid, wherein the STIM is in contact with the dielectric material at the top surface of the die.

Example 2 includes the subject matter of Example 1, and further specifies that the lid includes a hole, and at least a portion of the STIM is in the hole.

Example 3 includes the subject matter of Example 2, and further specifies that the hole is tapered.

Example 4 includes the subject matter of any of Examples 2-3, and further specifies that the hole narrows toward the die.

Example 5 includes the subject matter of any of Examples 1-4, and further specifies that the STIM has a thickness that is less than 200 microns.

Example 6 includes the subject matter of Example 5, and further specifies that the thickness of the STIM is greater than 50 microns.

Example 7 includes the subject matter of any of Examples 1-6, and further specifies that the lid includes a foot portion, and the foot portion includes a narrowed portion proximate to the package substrate.

Example 8 includes the subject matter of Example 7, and further specifies that the narrowed portion is in contact with the package substrate.

Example 9 includes the subject matter of any of Examples 7-8, and further includes: a sealant in contact with the narrowed portion.

Example 10 includes the subject matter of Example 9, and further includes: gaps in the sealant.

Example 11 includes the subject matter of any of Examples 1-10, and further specifies that the lid includes a metal layer, and the STIM is in contact with the metal layer.

Example 12 includes the subject matter of Example 11, and further specifies that the metal layer includes gold or silver.

Example 13 includes the subject matter of any of Examples 11-12, and further specifies that the metal layer has a thickness between Example 0.1 microns and 1 micron.

Example 14 includes the subject matter of any of Examples 11-13, and further specifies that the metal layer has a footprint larger than a footprint of the die.

Example 15 includes the subject matter of any of Examples 1-14, and further specifies that the lid includes a lip portion on an underside of the lid.

Example 16 includes the subject matter of Example 15, and further specifies that the STIM is in contact with the lip portion.

Example 17 includes the subject matter of any of Examples 15-16, and further specifies that the lip portion has a thickness between 100 microns and 500 microns.

Example 18 includes the subject matter of any of Examples 1-17, and further specifies that the STIM includes indium.

Example 19 includes the subject matter of any of Examples 1-18, and further specifies that the STIM includes tin, silver, gold, aluminum, or nickel.

Example 20 includes the subject matter of any of Examples 1-19, and further specifies that the STIM includes gallium.

Example 21 includes the subject matter of any of Examples 1-20, and further specifies that the lid includes copper or aluminum.

Example 22 includes the subject matter of Example 21, and further specifies that the lid includes nickel.

Example 23 includes the subject matter of any of Examples 1-22, and further specifies that the IC package is a ball grid array package.

Example 24 includes the subject matter of any of Examples 1-23, and further specifies that the lid includes a pedestal, and the die is between the pedestal and the package substrate.

Example 25 includes the subject matter of any of Examples 1-24, and further includes: an interposer, wherein the interposer is between the die and the package substrate.

Example 26 is an integrated circuit (IC) package, including: a package substrate; a die; a lid, wherein the die is between the package substrate and the lid, the lid includes a foot portion, and the foot portion includes a narrowed portion proximate to the package substrate; and a solder thermal interface material (STIM) between the die and the lid.

Example 27 includes the subject matter of Example 26, and further specifies that the die has a dielectric material at a top surface of the die, and the STIM is in contact with the dielectric material at the top surface of the die.

Example 28 includes the subject matter of Example 26, and further specifies that the die includes a metal layer, and the STIM is in contact with the metal layer.

Example 29 includes the subject matter of Example 28, and further specifies that the metal layer includes gold or silver.

Example 30 includes the subject matter of any of Examples 28-29, and further specifies that the metal layer has a thickness between Example 0.1 microns and 1 micron.

Example 31 includes the subject matter of any of Examples 26-30, and further specifies that the lid includes a hole, and at least a portion of the STIM is in the hole.

Example 32 includes the subject matter of Example 31, and further specifies that the hole is tapered.

Example 33 includes the subject matter of any of Examples 31-32, and further specifies that the hole narrows toward the die.

Example 34 includes the subject matter of any of Examples 26-33, and further specifies that the STIM has a thickness that is less than 200 microns.

Example 35 includes the subject matter of Example 34, and further specifies that the thickness of the STIM is greater than 50 microns.

Example 36 includes the subject matter of any of Examples 26-35, and further specifies that the narrowed portion is in contact with the package substrate.

Example 37 includes the subject matter of any of Examples 26-36, and further includes: a sealant in contact with the narrowed portion.

Example 38 includes the subject matter of Example 37, and further includes: gaps in the sealant.

Example 39 includes the subject matter of any of Examples 26-38, and further specifies that the lid includes a metal layer, the STIM is in contact with the metal layer.

Example 40 includes the subject matter of Example 39, and further specifies that the metal layer includes gold or silver.

Example 41 includes the subject matter of any of Examples 39-40, and further specifies that the metal layer has a thickness between Example 0.1 microns and 1 micron.

Example 42 includes the subject matter of any of Examples 39-41, and further specifies that the metal layer has a footprint larger than a footprint of the die.

Example 43 includes the subject matter of any of Examples 26-42, and further specifies that the lid includes a lip portion on an underside of the lid.

Example 44 includes the subject matter of Example 43, and further specifies that the STIM is in contact with the lip portion.

Example 45 includes the subject matter of any of Examples 43-44, and further specifies that the lip portion has a thickness between 100 microns and 500 microns.

Example 46 includes the subject matter of any of Examples 26-45, and further specifies that the STIM includes indium.

Example 47 includes the subject matter of any of Examples 26-46, and further specifies that the STIM includes tin, silver, gold, aluminum, or nickel.

Example 48 includes the subject matter of any of Examples 26-47, and further specifies that the STIM includes gallium.

Example 49 includes the subject matter of any of Examples 26-48, and further specifies that the lid includes copper or aluminum.

Example 50 includes the subject matter of Example 49, and further specifies that the lid includes nickel.

Example 51 includes the subject matter of any of Examples 26-50, and further specifies that the IC package is a ball grid array package.

Example 52 includes the subject matter of any of Examples 26-51, and further specifies that the lid includes a pedestal, and the die is between the pedestal and the package substrate.

Example 53 includes the subject matter of any of Examples 26-52, and further includes: an interposer, wherein the interposer is between the die and the package substrate.

Example 54 is an integrated circuit (IC) package, including: a package substrate; a die; a lid, wherein the die is between the package substrate and the lid, wherein the lid includes a lip portion on an underside of the lid; and a solder thermal interface material (STIM) between the die and the lid.

Example 55 includes the subject matter of Example 54, and further specifies that the die has a dielectric material at a top surface of the die, and the STIM is in contact with the dielectric material at the top surface of the die.

Example 56 includes the subject matter of Example 54, and further specifies that the die includes a metal layer, and the STIM is in contact with the metal layer.

Example 57 includes the subject matter of Example 56, and further specifies that the metal layer includes gold or silver.

Example 58 includes the subject matter of any of Examples 56-57, and further specifies that the metal layer has a thickness between Example 0.1 microns and 1 micron.

Example 59 includes the subject matter of any of Examples 54-58, and further specifies that the lid includes a hole, and at least a portion of the STIM is in the hole.

Example 60 includes the subject matter of Example 59, and further specifies that the hole is tapered.

Example 61 includes the subject matter of any of Examples 59-60, and further specifies that the hole narrows toward the die.

Example 62 includes the subject matter of any of Examples 54-61, and further specifies that the STIM has a thickness that is less than 200 microns.

Example 63 includes the subject matter of Example 62, and further specifies that the thickness of the STIM is greater than 50 microns.

Example 64 includes the subject matter of any of Examples 54-63, and further specifies that the lid includes a foot portion, and the foot portion includes a narrowed portion proximate to the package substrate.

Example 65 includes the subject matter of Example 64, and further specifies that the narrowed portion is in contact with the package substrate.

Example 66 includes the subject matter of any of Examples 64-65, and further includes: a sealant in contact with the narrowed portion.

Example 67 includes the subject matter of Example 66, and further includes: gaps in the sealant.

Example 68 includes the subject matter of any of Examples 54-67, and further specifies that the lid includes a metal layer, and the STIM is in contact with the metal layer.

Example 69 includes the subject matter of Example 68, and further specifies that the metal layer includes gold or silver.

Example 70 includes the subject matter of any of Examples 68-69, and further specifies that the metal layer has a thickness between Example 0.1 microns and 1 micron.

Example 71 includes the subject matter of any of Examples 68-70, and further specifies that the metal layer has a footprint larger than a footprint of the die.

Example 72 includes the subject matter of any of Examples 54-71, and further specifies that the STIM is in contact with the lip portion.

Example 73 includes the subject matter of any of Examples 54-72, and further specifies that the lip portion has a thickness between 100 microns and 500 microns.

Example 74 includes the subject matter of any of Examples 54-73, and further specifies that the STIM includes indium.

Example 75 includes the subject matter of any of Examples 54-74, and further specifies that the STIM includes tin, silver, gold, aluminum, or nickel.

Example 76 includes the subject matter of any of Examples 54-75, and further specifies that the STIM includes gallium.

Example 77 includes the subject matter of any of Examples 54-76, and further specifies that the lid includes copper or aluminum.

Example 78 includes the subject matter of Example 77, and further specifies that the lid includes nickel.

Example 79 includes the subject matter of any of Examples 54-78, and further specifies that the IC package is a ball grid array package.

Example 80 includes the subject matter of any of Examples 54-79, and further specifies that the lid includes a pedestal, and the die is between the pedestal and the package substrate.

Example 81 includes the subject matter of any of Examples 54-80, and further includes: an interposer, wherein the interposer is between the die and the package substrate.

Example 82 is an integrated circuit (IC) package, including: a package substrate; a die; a lid, wherein the die is between the package substrate and the lid; and a solder thermal interface material (STIM) between the die and the lid, wherein the STIM has a thickness that is less than 200 microns.

Example 83 includes the subject matter of Example 82, and further specifies that the die has a dielectric material at a top surface of the die, and the STIM is in contact with the dielectric material at the top surface of the die.

Example 84 includes the subject matter of Example 82, and further specifies that the die includes a metal layer, and the STIM is in contact with the metal layer.

Example 85 includes the subject matter of Example 84, and further specifies that the metal layer includes gold or silver.

Example 86 includes the subject matter of any of Examples 84-85, and further specifies that the metal layer has a thickness between Example 0.1 microns and 1 micron.

Example 87 includes the subject matter of any of Examples 82-86, and further specifies that the lid includes a hole, and at least a portion of the STIM is in the hole.

Example 88 includes the subject matter of Example 87, and further specifies that the hole is tapered.

Example 89 includes the subject matter of any of Examples 87-88, and further specifies that the hole narrows toward the die.

Example 90 includes the subject matter of any of Examples 82-89, and further specifies that the thickness of the STIM is greater than 50 microns.

Example 91 includes the subject matter of any of Examples 82-90, and further specifies that the lid includes a foot portion, and the foot portion includes a narrowed portion proximate to the package substrate.

Example 92 includes the subject matter of Example 91, and further specifies that the narrowed portion is in contact with the package substrate.

Example 93 includes the subject matter of any of Examples 91-92, and further includes: a sealant in contact with the narrowed portion.

Example 94 includes the subject matter of Example 93, and further includes: gaps in the sealant.

Example 95 includes the subject matter of any of Examples 82-94, and further specifies that the lid includes a metal layer, and the STIM is in contact with the metal layer.

Example 96 includes the subject matter of Example 95, and further specifies that the metal layer includes gold or silver.

Example 97 includes the subject matter of any of Examples 95-96, and further specifies that the metal layer has a thickness between Example 0.1 microns and 1 micron.

Example 98 includes the subject matter of any of Examples 95-97, and further specifies that the metal layer has a footprint larger than a footprint of the die.

Example 99 includes the subject matter of any of Examples 82-98, and further specifies that the lid includes a lip portion on an underside of the lid.

Example 100 includes the subject matter of Example 99, and further specifies that the STIM is in contact with the lip portion.

Example 101 includes the subject matter of any of Examples 99-100, and further specifies that the lip portion has a thickness between 100 microns and 500 microns.

Example 102 includes the subject matter of any of Examples 82-101, and further specifies that the STIM includes indium.

Example 103 includes the subject matter of any of Examples 82-102, and further specifies that the STIM includes tin, silver, gold, aluminum, or nickel.

Example 104 includes the subject matter of any of Examples 82-103, and further specifies that the STIM includes gallium.

Example 105 includes the subject matter of any of Examples 82-104, and further specifies that the lid includes copper or aluminum.

Example 106 includes the subject matter of Example 105, and further specifies that the lid includes nickel.

Example 107 includes the subject matter of any of Examples 82-106, and further specifies that the IC package is a ball grid array package.

Example 108 includes the subject matter of any of Examples 82-107, and further specifies that the lid includes a pedestal, and the die is between the pedestal and the package substrate.

Example 109 includes the subject matter of any of Examples 82-108, and further includes: an interposer, wherein the interposer is between the die and the package substrate.

Example 110 is an integrated circuit (IC) assembly, including: an IC package in accordance with any of Examples 1-109; and a circuit board coupled to the IC package.

Example 111 includes the subject matter of Example 110, and further specifies that the circuit board is a motherboard.

Example 112 includes the subject matter of any of Examples 110-111, and further includes: a heat sink, wherein the lid is between the heat sink and the circuit board.

Example 113 includes the subject matter of Example 112, and further includes: a polymer TIM between the lid and the heat sink.

Example 114 includes the subject matter of any of Examples 110-113, and further includes: a housing around the IC package and the circuit board.

Example 115 includes the subject matter of any of Examples 110-114, and further includes: wireless communication circuitry communicatively coupled to the circuit board.

Example 116 includes the subject matter of any of Examples 110-115, and further includes: a display communicatively coupled to the circuit board.

Example 117 includes the subject matter of any of Examples 110-116, and further specifies that the IC assembly is a mobile computing device.

Example 118 includes the subject matter of any of Examples 110-116, and further specifies that the IC assembly is a server computing device.

Example 119 includes the subject matter of any of Examples 110-116, and further specifies that the IC assembly is a wearable computing device.

Example 120 includes the subject matter of any of Examples 110-119, and further specifies that the IC package is coupled to the circuit board by ball grid array interconnects.

Example 121 includes the subject matter of any of Examples 110-120, and further specifies that the lid has a concave interior surface.

Example 122 is a method of manufacturing an integrated circuit (IC) package, including: positioning a lid over a die, wherein the lid includes a hole above the die; and dispensing liquid solder thermal interface material (STIM) through the hole and onto the die.

Example 123 includes the subject matter of Example 122, and further includes: allowing the liquid STIM to solidify.

Example 124 includes the subject matter of any of Examples 122-123, and further includes: before dispensing the liquid STIM, cleaning a top surface of the die and a bottom surface of the lid.

1. An integrated circuit (IC) package, comprising:
a package substrate;
a die having a dielectric material at a top surface;
a lid, wherein the die is between the package substrate and the lid; and
a solder thermal interface material (STIM) between the die and the lid, wherein the STIM is in contact with the dielectric material at the top surface of the die.

2. The IC package of claim 1, wherein the lid includes a hole, and at least a portion of the STIM is in the hole.

3. The IC package of claim 2, wherein the hole is tapered.

4. The IC package of claim 2, wherein the hole narrows toward the die.

5. The IC package of claim 1, wherein the lid includes a metal layer, and the STIM is in contact with the metal layer.

6. The IC package of claim 5, wherein the metal layer includes gold or silver.

7. An integrated circuit (IC) package, comprising:
a package substrate;
a die;
a lid, wherein the die is between the package substrate and the lid, the lid includes a foot portion, and the foot portion includes a narrowed portion proximate to the package substrate; and
a solder thermal interface material (STIM) between the die and the lid.

8. The IC package of claim 7, wherein the die has a dielectric material at a top surface of the die, and the STIM is in contact with the dielectric material at the top surface of the die.

9. The IC package of claim 7, wherein the lid includes a hole, and at least a portion of the STIM is in the hole.

10. The IC package of claim 7, wherein the narrowed portion is in contact with the package substrate.

11. The IC package of claim 7, further comprising:
a sealant in contact with the narrowed portion.

12. The IC package of claim 11, further comprising:
gaps in the sealant.

13. An integrated circuit (IC) package, comprising:
a package substrate;
a die;
a lid, wherein the die is between the package substrate and the lid; and
a solder thermal interface material (STIM) between the die and the lid, wherein the STIM has a thickness that is less than 200 microns.

14. The IC package of claim 13, wherein the die has a dielectric material at a top surface of the die, and the STIM is in contact with the dielectric material at the top surface of the die.

15. The IC package of claim 13, wherein the die includes a metal layer, and the STIM is in contact with the metal layer.

16. The IC package of claim 13, wherein the lid includes a lip portion on an underside of the lid.

17. The IC package of claim 16, wherein the STIM is in contact with the lip portion.

18. The IC package of claim 16, wherein the lip portion has a thickness between 100 microns and 500 microns.

19. The IC package of claim 13, wherein the STIM includes indium.

20. The IC package of claim 13, wherein the lid includes copper or aluminum.
